(19) United States
(12) Patent Application Publication
(10) Pub. No.: US 2023/0323154 A1
(43) Pub. Date: Oct. 12, 2023

(54) ADHESION BETWEEN BASE MATERIAL AND RESILIENT MATERIAL LAYER

(71) Applicant: COMOTOMO 2022 INC., Sunnyvale, CA (US)

(72) Inventors: Sang Pyo Kim, Los Altos, CA (US); SeungJin Yun, Gwangju-si (KR)

(21) Appl. No.: 17/718,674

(22) Filed: Apr. 12, 2022

(51) Int. Cl. C09D 183/06; C08J 7/043; C08J 7/04

(52) U.S. Cl. CPC C09D 183/06; C08J 7/043; C08J 7/042; C08J 2383/06

(57) ABSTRACT

Embodiments relate to improving the adhesion between a base substrate and a resilient material layer. Plasma-enhanced chemical vapor deposition (PECVD) is performed to deposit a silicon compound layer on a base substrate. A resilient material layer is formed on the surface of the silicon compound layer. An object formed by the method may include the base substrate, a silicon compound layer on the base substrate, and the resilient material layer on a surface of the silicon compound layer. By having a silicon compound layer with a surface roughness and thickness, adhesion between the base substrate and the resilient material layer can be significantly improved.

### BACKGROUND

### 1. Field of Art

The disclosure relates to a silicon compound layer for improving adhesion between a base substrate and a resilient material layer.

### 2. Description of the Related Art

Objects having a base substrate bonded to a resilient material layer have high utility and are widely used in various applications. The base substrate may be formed of glass, metal, plastic, etc. In particular, objects including a base substrate bonded to a silicone rubber layer as the resilient material may be used in, for example, household goods, car parts, and electronic components baby bottles, goggles, bathroom products, which involve heat-resistance and/or transparency and chemical safety.

Typically, the resilient material is bonded to the base substrate by enhancing adhesive properties of the silicone rubber layer, applying primer on the surface of the base substrate, and attaching hardened silicone rubber and the base material using an adhesive. However, enhancing the adhesive properties of the silicone rubber layer is often achieved by addition of highly reactive materials (e.g., carbon functional silane) that leads to poor heat-resistance and distortion of the object. Moreover, the reactive materials can also adhere to the mold itself during injection molding, making it difficult to control the quality of the molding process.

In addition, applying primer on the surface of the base substrate involves complex processes of applying, drying, and baking the primer, and can create defects due to non-uniform application of the primer. While there are other methods to improve adhesion properties of the base substrate (e.g., ultraviolet irradiation, plasma treatment, and corona treatment), these other methods do not sufficiently improve the adhesive properties to the base material, and often require dangerous working environments and expensive machinery. Moreover, attaching the silicone rubber layer to the base material using an adhesive may also be difficult, since adhesives usually have poor heat-resistance or durability and may be destroyed in the manufacturing process.

### SUMMARY

Embodiments relate to an article of manufacture including a base substrate, a silicon compound layer on the base substrate, and a resilient material layer on the surface of the silicon compound layer. The silicon compound layer has a surface roughness between 50 nm and 600 nm in units of Ra.

In one or more embodiments, the thickness of the silicon compound layer is less than 1000 nm but more than 50 nm.

In one or more embodiments, the silicon compound layer is a SiOₓC_{y}H_{z} layer.

In one or more embodiments, the SiOₓC_{y}H_{z} layer includes 28-30 wt % of silicon, 60-65 wt % of oxygen, 0-1 wt % of carbon and 6-9 wt % of hydrogen.

In one or more embodiments, the base substrate includes at least one of thermo-plastic polymer, thermo-setting polymer, silicone rubber, metals, and glass.

In one or more embodiments, the thermo-plastic polymer is at least one of polypropylene (PP), polyester sulfone (PES), polyphenyl sulfone (PPSU), polyamide (PA), tritan, polycarbonate (PC), and nylon.

In one or more embodiments, the resilient material layer is a material selected from a group consisting of liquid silicone rubber (LSR), heat cured rubber (HCR) silicone, and a combination thereof.

In one or more embodiments, the base substrate is PPSU, and the resilient material layer is silicone rubber.

In one or more embodiments, the silicon compound layer is deposited on the base substrate using plasma-enhanced chemical vapor deposition (PECVD).

In one or more embodiments, the PECVD is performed by reacting a precursor hexamethyldisiloxane (HMIDSO) with a reactivity gas oxygen (O₂) under plasma.

Embodiments also relate to a method of manufacturing an article of manufacture. Plasma-enhanced chemical vapor deposition (PECVD) is performed to deposit a silicon compound layer on a base substrate of an article of manufacture. A resilient material layer is formed on a surface of the silicon compound layer.

In one or more embodiments, the thickness of the silicon compound layer is less than 1000 nm but more than 50 nm.

In one or more embodiments, a surface roughness of the silicon compound layer is between 50 nm and 600 nm in units of Ra.

In one or more embodiments, the silicon compound layer is a SiOₓC_{y}H_{z} layer.

In one or more embodiments, the SiOₓC_{y}H_{z} layer comprises 28-30 wt % of silicon, 60-65 wt % of oxygen, 0-1 wt % of carbon and 6-9 wt % of hydrogen.

In one or more embodiments, the base substrate comprises at least one of thermo-plastic polymer, thermo-setting polymer, silicone rubber, metals, and glass.

In one or more embodiments, the thermo-plastic polymer is at least one of polypropylene (PP), polyester sulfone (PES), polyphenyl sulfone (PPSU), polyamide (PA), tritan, polycarbonate (PC), and nylon.

In one or more embodiments, the resilient material layer is a material selected from a group consisting of liquid silicone rubber (LSR), heat cured rubber (HCR) silicone, and a combination thereof.

In one or more embodiments, the base substrate is PPSU, and the resilient material layer is silicone rubber.

In one or more embodiments, performing the PECVD comprises reacting a precursor hexamethyldisiloxane (HMDSO) with a reactivity gas oxygen (O₂) under plasma.

In one or more embodiments, wherein forming the resilient material layer comprises injecting a liquid form of resilient material into a mold placed with the base substrate that is deposited with the resilient material layer.

### BRIEF DESCRIPTION OF THE DRAWINGS

FIG. 1 is a flowchart illustrating a method of bonding a resilient material layer to a base substrate, according to one embodiment.

FIG. 2 illustrates a structure of a base substrate, a silicon compound layer, and a resilient material layer, according to one embodiment.

FIG. 3 is a diagram illustrating a cross sectional view taken across a surface of a polymer material substrate without any silicon compound layer deposited thereon, according to a comparative example.

FIG. 4A through 4C are cross sectional views taken across surfaces of polymeric material substrates, each with a silicon compound layer of a thickness below a threshold level and roughness below a threshold level, according to some embodiments.

FIG. 5A through 5C are cross sectional views taken across surfaces of polymeric material substrates, each with a silicon compound layer of a thickness below a threshold and roughness within the threshold range, according to some embodiment.

FIG. 6 is a cross sectional view taken across a surface of a polymeric material substrate with a silicon compound layer of a thickness above a threshold and roughness within a threshold range, according to one embodiment.

FIG. 7 is a cross sectional view taken across a surface of a polymeric material substrate with a silicon compound layer of a thickness below a threshold and roughness above the threshold range, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments. In the drawings, like reference numerals in the drawings denote like elements. The shape, size and regions, and the like, of the drawing may be exaggerated for clarity.

Embodiments relate to articles of manufacture having a base substrate bonded to a resilient material layer and method for manufacturing such articles. A silicon compound layer with a predefine degree of surface roughness is deposited on the base substrate, and the resilient material layer is disposed on the silicon compound layer to enhance adhesion between the base substrate and the resilient material layer. The silicon compound layer of an average thickness less 1000 nm, and surface roughness of 50 nm to 600 nm in units of Ra may be deposited using a plasma-enhanced chemical vapor deposition (PECVD) method. Such articles of manufacture may be used as a high heat-resistance part (e.g., car parts and electronic components) or components that are transparent and chemically safe (e.g., baby bottles, goggles and bathroom products).

### Method Of Bonding Resilient Material Layer to Base Substrate

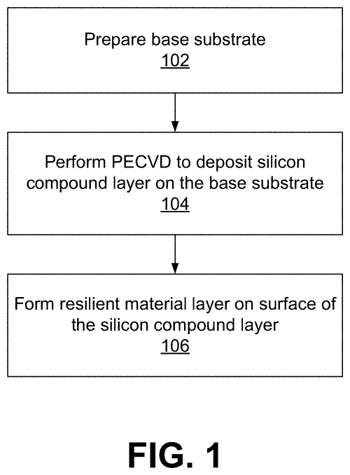

FIG. 1 is a flowchart illustrating a method of bonding a resilient material layer to a base substrate, according to one embodiment. The following embodiments are described with reference to using a silicone rubber layer as the resilient material layer, but is not limited hereto, and different materials may be used as the resilient material layer.

First, a base substrate is prepared 102 for an object. The base substrate may be formed from at least one of thermo-plastic polymer, thermo-setting polymer, silicone rubber, metals such as stainless steel, aluminum, gold, silver, copper, iron, inorganic materials such as aluminum oxide, titanium oxide and glass. In particular, when the base substrate includes thermo-plastic polymer, the base substrate may be formed of at least one of polypropylene (PP), polyester sulfone (PES), polyphenyl sulfone (PPSU), polyamide (PA), tritan, polycarbonate (PC), and nylon. These thermo-plastic polymers have high heat-resistance and impact resistance. Thus, base substrates including thermo-plastic polymer may be advantageous in applications for medical devices, baby products, kitchen products, and the like that require repetitive sterilization with high temperature and moisture.

Then, a deposition method is performed 104 to deposit a silicon compound layer on the base substrate. The silicon compound layer may be a layer of SiOₓC_{y}H_{z} which is predominantly silicon dioxide. In particular, the SiOₓC_{y}H_{z} layer has an average thickness below 1000 nm and a surface roughness from 50 nm to 600 nm in units of Ra. Ra indicates the arithmetic average of the absolute values of the profile height deviations from the mean line of a surface of the layer. The range of surface roughness and the thickness of the SiOₓC_{y}H_{z} effective to the adhesion of silicone to the base substrate was determined based on experiments described below in detail with reference to FIGS. 3 to 7.

The surface roughness of the silicon compound layer (e.g., SiOₓC_{y}H_{z} layer) may be measured using an atomic force microscopy (AFM) as described, for example, in Ichiko Misuzu et al., “Profile Surface Roughness Measurement Using Metrological Atomic Force Microscope and Uncertainty Evaluation,” 11^{th} Laser Metrology for Precision Measurement and Inspection in Industry 2014 (Sep. 2-5, 2014), which is incorporated by reference herein in its entirety. The surface roughness of the examples described below with reference to FIGS. 3 through 7 were measure using the same method.

The thickness of the silicon compound layer (e.g., SiOₓC_{y}H_{z} layer) may be determined by analyzing the images of the scanning electron microscope (SEM). First, the surface of the substrate with or without the silicon compound is pre-treated with platinum coating to prevent any damage to the silicon compound layer. Then, the pre-treated surface is processed using focused ion beam (FIB). The cross section of the surface treated with the FIB is then captured using the SEM. Pixels of the captured image are then analyzed to determine thicknesses at multiple points in the image. An average value of the thicknesses at the multiple points is taken as the thickness of the silicon compound layer.

In one embodiment, the silicon compound layer having surface roughness is achieved by performing plasma-enhanced chemical deposition (PECVD) to deposit the silicon compound layer. In one instance, the PECVD process may be performed under relatively low-temperature and low-pressure conditions to obtain the desired surface roughness of the silicon compound layer on the base substrate. The pressure for the PECVD process may be from 1×10⁻² to 1 Torr, and the temperature of the base substrate during at least a part or entirety of the PECVD process may be from 50° C. to 200° C. A Si-containing precursor gas and a reactivity gas may be used in the PECVD process. The Si-containing precursor is hexamethyldisiloxane (HMDSO) and the reactivity gas is oxygen (O₂).

The silicon compound layer formed by such PECVD process may be a SiOₓC_{y}H_{z} layer. In one or more embodiments, the ratio of silicon, oxygen, carbon and hydrogen is in the range of 28-30 wt %, 60-65 wt %, 0-1 wt % and 6-9 wt %, respectively. The composition of the silicon compound layer may be determined, for example, using Rutherford Backscattering Spectrometry (RBS)—Elastic Recoil Detection (ERD) method, as well known in the art.

Returning to FIG. 1, a resilient material layer is formed 106 on the surface of the silicon compound layer. Specifically, the resilient material layer may be formed by applying a resilient material on a surface of the silicon compound layer having the surface roughness within a threshold range. The effect is to improve adhesion between the base substrate and the resulting resilient material layer. The resilient material may be LSR, HCR or a combination thereof.

In one embodiment, the resilient material is applied to the base substrate having the silicon compound layer by placing or fixing an object including the base substrate and the silicon compound layer in a mold of an injection molding machine, and filling the mold of the injection machine with the resilient material to apply the resilient material on the surface of the silicon compound layer.

In one embodiment, plasma treatment is performed on the surface of the base substrate before depositing the silicon compound layer. Performing plasma treatment reduces contamination or other particles on the base substrate, and results in improved adhesion between the base substrate and the deposited silicon compound layer.

Further, an ionization process may be performed on a surface of the silicon compound layer before forming the resilient material layer. Although the relative high surface roughness of the silicon compound layer improves physical and mechanical adhesion with the resilient material layer, performing an ionization process can further improve adhesion by increasing the surface energy of the surface of the silicon compound layer.

### Composite Structure

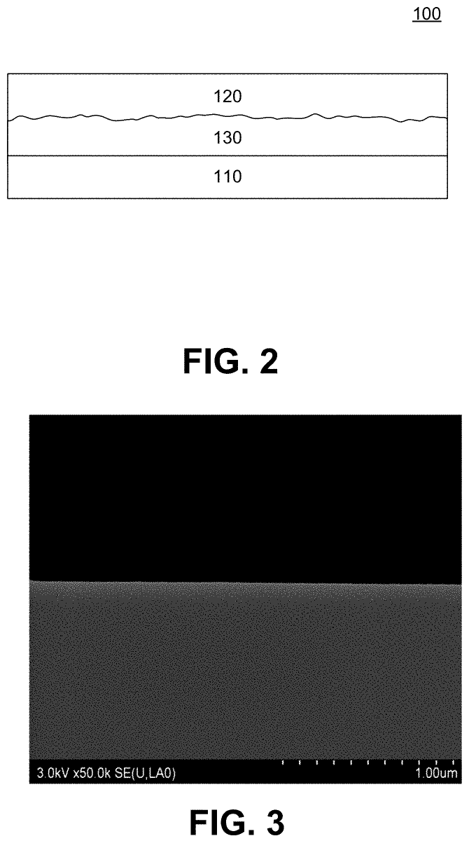

FIG. 2 illustrates a composite structure 100 including a base substrate 110, a silicon compound layer 130, and a resilient material layer 120, according to one embodiment. The following composite structure 100 may form a part or entirety of an article, and may be obtained by performing the steps described in detail in conjunction with FIG. 1.

The base substrate 110 forms as a base material for the composite structure 100, and may be formed from materials and properties described in conjunction with step 102 of the method illustrated in FIG. 1. The resilient material layer 120 provides texture and impact resistance to the object formed of the composite structure 100, and may be formed from materials and properties described in conjunction with forming 106 of resilient material layer described above in conjunction with FIG. 1.

The silicon compound layer 130 is formed between the base substrate 110 and the resilient material layer 120, and is formed from materials and properties described in conjunction with step 104 of the method illustrated in FIG. 1. In particular, the surface of the silicon compound layer 130 interfacing the resilient material layer 120 may have a surface roughness within a threshold range to improve bonding of the resilient material layer 120 to the base substrate 110. The silicon compound layer 130 may also have an average thickness below a threshold. In one example, the base substrate 110 may be formed of PPSU, the resilient material layer 120 may be formed of silicone rubber while the silicon compound layer 130 may have a surface roughness within 50 nm to 600 nm and an average thickness less than 1000 nm but more than 50 nm.

### Experimental Results

In the following examples, adhesion of silicone to a container of a baby bottle made of PPSU using a SiOₓC_{y}H_{z} layer was tested. In the examples, ionization procedure was performed to activate the surface of the PPSU and then a PECVD process involving HMDSO as the Si-containing precursor and O₂ as the reactivity gas was used to form the SiOₓC_{y}H_{z} layer. Then the PPSU substrate in the form of a baby bottle with the SiOₓC_{y}H_{z} layer is placed in a mold of an injection molding machine, and then the mold is filled with LSR silicone. The PPSU substrate with the LSR silicone is then cooled to cure the silicone. After attaching the silicone to the PPSU via the SiOₓC_{y}H_{z} layer, the baby bottle was immersed in a boiling water for a predetermined amount of time at pressure of 2 atm to determine if the adhesion between the PPSU and the silicone was maintained. No separate adhesive was placed between the SiOₓC_{y}H_{z} layer and the silicone to attach the silicone to the PPSU substrate.

FIG. 3 is a scanning electron microscope (SEM) image of a cross section view taken across a surface of a PPSU substrate and silicone without any SiOₓC_{y}H_{z} layer deposited, according to a comparative example. Hence, the thickness of the SiOₓC_{y}H_{z} layer was zero and the roughness of the PPSU substrate was less than 5 nm (Ra). Without the presence of the SiOₓC_{y}H_{z} layer, the silicone separated from the PPSU even before being immersed in the boiling water.

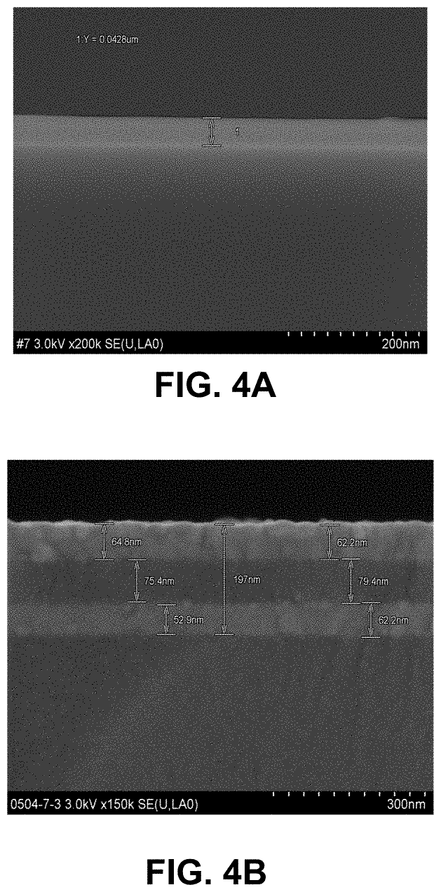

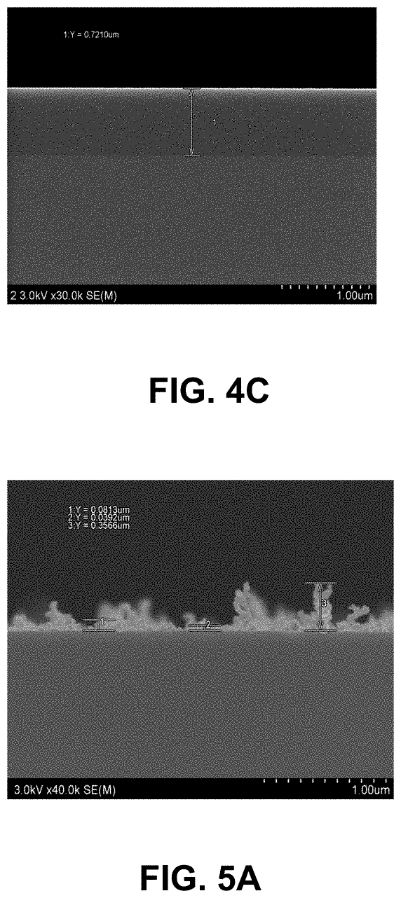

FIG. 4A through 4C are SEM images of cross sectional views taken across the surfaces of PPSU substrates with the SiOₓC_{y}H_{z} layer below a threshold level of roughness, according to some embodiments. That is, the roughness of the SiOₓC_{y}H_{z} layer was lower than 50 nm (Ra). FIG. 4A is a SEM image of the PPSU substrate where the average thickness of the SiOₓC_{y}H_{z} layer was 42.8 nm and the roughness of the SiOₓC_{y}H_{z} layer was 0.26 nm (Ra). FIG. 4B is a SEM image of the PPSU substrate where the thickness of the SiOₓC_{y}H_{z} layer was 197 nm and the roughness of the SiOₓC_{y}H_{z} layer was 11.15 nm (Ra). In this example, three separate cycles of PECVD was performed to obtain the SiOₓC_{y}H_{z} layer of the final thickness. FIG. 4C is a SEM image of the PPSU substrate where the thickness of the SiOₓC_{y}H_{z} layer was 721 nm and the roughness of the SiOₓC_{y}H_{z} layer was 25.64 nm (Ra). In the examples of FIGS. 4A through 4C, silicone initially attached to the PPSU substrate but then separated when the substrate and the silicone were immersed in the boiling water for 30 hours. Hence, these examples show that the silicone was not adequately attached to the substrate if the roughness of the SiOₓC_{y}H_{z} layer was lower than 50 nm (Ra) even if the thickness of the SiOₓC_{y}H_{z} layer was less than 1000 nm.

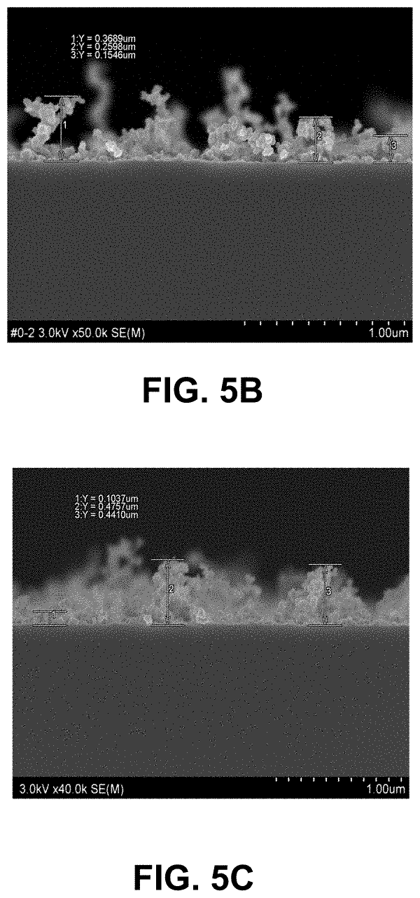

FIG. 5A through 5C are SEM images of cross sectional views taken across the surfaces of PPSU substrates with the SiOₓC_{y}H_{z} layer of roughness within a predetermined range, according to some embodiments. That is, the roughness of the SiOₓC_{y}H_{z} layer was 50 nm (Ra) or more but lower than 600 nm (Ra). FIG. 5A is a SEM image of the PPSU substrate where the average thickness of the SiOₓC_{y}H_{z} layer was 127.3 nm and the roughness of the SiOₓC_{y}H_{z} layer was 56.85 nm (Ra). FIG. 5B is a SEM image of the PPSU substrate where the average thickness of the SiOₓC_{y}H_{z} layer was 263.1 nm and the roughness of the SiOₓC_{y}H_{z} layer was 203.4 nm (Ra). FIG. 5C is a SEM image of the PPSU substrate where the average thickness of the SiOₓC_{y}H_{z} layer was 400.7 nm and the roughness of the SiOₓC_{y}H_{z} layer was 454 nm (Ra). In the examples of FIGS. 5A through 5C, silicone attached to the PPSU substrate and remained attached to the substrate even after the substrate and the silicone were immersed in the boiling water for 50 hours. Hence, these examples show that the silicone was adequately attached to the substrate if the roughness of the SiOₓC_{y}H_{z} layer is in a threshold range of 50 nm (Ra) to 600 nm (Ra) and the average thickness of the SiOₓC_{y}H_{z} layer is less than 1000 nm.

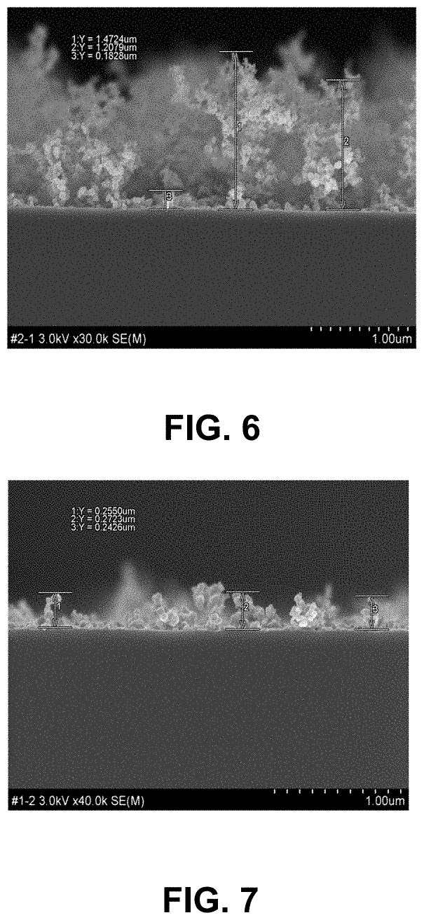

FIG. 6 is a SEM image of a cross sectional view taken across the surface of a PPSU substrate where the roughness of the SiOₓC_{y}H_{z} layer is within the threshold range but the average thickness the SiOₓC_{y}H_{z} layer is above the threshold level, according to some embodiments. Specifically, the average thickness of the SiOₓC_{y}H_{z} layer was 1,207.9 nm and roughness of the SiOₓC_{y}H_{z} layer was 224.1 nm (Ra). In this example, the silicone was initially attached to the PPSU substrate but separated from the substrate after 30 hours immersion in the boiling water. This example shows that the silicone is not adequately attached to the substrate if the thickness of the SiOₓC_{y}H_{z} layer is greater than 1000 nm.

FIG. 7 is a cross sectional view taken across a surface of a PPSUsubstate with a silicon compound layer of a thickness below a threshold level and roughness above the threshold range, according to one embodiment. In the example of FIG. 7, the thickness of the SiOₓC_{y}H_{z} layer was 256.6 nm and the roughness of the SiOₓC_{y}H_{z} layer was 732 nm (Ra). In this example, the silicone was initially attached to the PPSU substrate but separated from the substrate after 30 hours immersion in the boiling water. This example show that the silicone is not adequately attached to the substrate if the roughness of the SiOₓC_{y}H_{z} layer is over 600 nm (Ra) even when the thickness of the SiOₓC_{y}H_{z} layer is below 1000 nm.

Experiments were also performed using materials other than PPSU as a base substrate. Specifically, lap-shear tests according to ASTM D1002 was performed using two specimen pieces where each of the specimen piece was deposited with a silicon compound layer (e.g., SiOxCyHz layer). LSR was then coated on a surface of one specimen piece deposited with the silicon compound layer. The other specimen piece was then overlapped with the surface deposited with the silicon compound layer facing the LSR coated surface. The specimen pieces were pressed so that the LSR reached a predetermined thickness (e.g., 1 mm), and then baked to cure the LSR into silicone. Then the two specimen pieces were pulled in opposite directions to test the failure shear force at the overlapping part of the specimen pieces.

Maximum shear force before the failure was measured for different materials (e.g., polycarbonate, glass, polypropylene, and stainless steel) as the specimen materials to test applicability of the silicon compound to these materials. The SiOₓC_{y}H_{z} layers were deposited under similar PECVD conditions as examples of FIGS. 5A through 5C, and therefore, are presumed to have the thickness less than 1000 nm and the roughness in the range of 50 nm (Ra) to 600 nm (Ra). The lap-shear tests were performed three times for each material with or without a SiOxCyHz layer, and the averaged maximum sheer force were compared. The results are follows:

TABLE 1

| | | |
|---|---|---|
| | Maximum | Maximum |
| | Shear | Shear |
| | Force | Force |
| | without | with |
| | SiOxCyHz | SiOxCyHz |
| Sample | layer | layer |
| Material | (unit: Newton) | (unit: Newton) |

| | | | | |
|---|---|---|---|---|
| Polycarbonate | 91.7 | N | 1620.7 | N |
| Glass | 209.3 | N | 410 | N |
| Polypropylene | 136.7 | N | 967 | N |
| Stainless steel | 4 | N | 2765.3 | N |
| (SUS304) | | | | |

As shown in Table 1, there was a considerable increase in the maximum shear force when the SiOxCyHz layer was deposited on the sample materials. In the case of stainless steel, the increased shear force due to deposition of the SiOxCyHz layer was approximately 691 times. Although only PPSU, polycarbonate, glass, polypropylene and stainless steel were used as the materials of the basis substrate, similar results are expected in other materials.

Although the present disclosure has been described above with respect to several embodiments, various modifications can be made within the scope of the disclosure. Accordingly, the disclosure described above is intended to be illustrative, but not limiting.

1. An article of manufacture, comprising:
a base substrate;
a silicon compound layer on the base substrate, the silicon compound layer having an outer surface with a surface roughness between 50 nm and 600 nm in units of Ra; and
a resilient material layer on the outer surface of the silicon compound layer.

2. The article of manufacture of claim 1, wherein a thickness of the silicon compound layer is less than 1000 nm but more than 50 nm.

3. The article of manufacture of claim 2, wherein the silicon compound layer comprises 28-30 wt % of silicon, 60-65 wt % of oxygen, 0-1 wt % of carbon and 6-9 wt % of hydrogen.

4. (canceled)

5. The article of manufacture of claim 1, wherein the base substrate comprises at least one of thermo-plastic polymer, thermo-setting polymer, silicone rubber, metals, and glass.

6. The article of manufacture of claim 5, wherein the thermo-plastic polymer is at least one of polypropylene, polyester sulfone, polyphenyl sulfone, polyamide, polycarbonate, and nylon.

7. The article of manufacture of claim 1, wherein the resilient material layer is a material selected from a group consisting of liquid silicone rubber, heat cured rubber silicone, and a combination thereof.

8. The article of manufacture of claim 3, wherein the base substrate is polyphenyl sulfone, and the resilient material layer is silicone rubber.

9. The article of manufacture of claim 1, wherein the silicon compound layer is deposited on the base substrate using plasma-enhanced chemical vapor deposition.

10. The article of manufacture of claim 9, wherein the plasma-enhanced chemical vapor deposition is performed by reacting a precursor hexamethyldisiloxane with a reactivity gas oxygen under plasma.

11-21. (canceled)
